(19) United States
(12) Patent Application Publication
(10) Pub. No.: US 2013/0156995 A1
(43) Pub. Date: Jun. 20, 2013

(54) Partially Metalized Plastic Product And Manufacturing Process

(71) Applicant: Albea Services, Gennevilliers (FR)

(72) Inventors: Ed Crutchley, Tunbridge Wells Kent (GB); Cecile Ghesquiere, Plouhinec (FR)

(73) Assignee: Albea Services, Gennevilliers (FR)

(21) Appl. No.: 13/714,614

(22) Filed: Dec. 14, 2012

(30) Foreign Application Priority Data
Dec. 15, 2011 (FR) 1161735

(51) Int. Cl. B32B 15/085; C23C 14/34; B32B 3/04

(52) U.S. Cl. CPC B32B 15/085; B32B 3/04; C23C 14/34
USPC 428/76; 428/522; 204/192.1

(57) ABSTRACT

An at least partially metalized plastic product for cosmetic and perfume packaging comprising a plastic body, the plastic body being directly covered at least partially by a metal layer, wherein the plastic is a polyolefin selected from: polyethylene, polypropylene, their copolymer or their mixture;

and in that when the polyolefin comprises at least one polypropylene or a copolymer of polypropylene-polyethylene, this polyolefin has an infrared spectrum having:
a peak at the wave number of 720 cm⁻¹ of a height at least equal to 20; or
a peak at the wave number of 809 cm⁻¹ of a height less than 20, a peak at the wave number of 840 cm⁻¹ of a height less than 50, a peak at the wave number of 899 cm⁻¹ of a height less than 20, and a peak at the wave number of 997 cm⁻¹ of a height less than 60.

### FIELD OF THE INVENTION

The invention relates to an at least partially metalized plastic product comprising a plastic body. In particular, the invention relates to such a plastic product in which the plastic body is directly at least partially covered by a metal layer, the plastic being a polyolefin selected from polyethylene, polypropylene, polypropylene copolymer or a mixture thereof. The invention further relates to a manufacturing process of such a plastic product by vacuum metallisation.

### PRIOR ART

Plastic products which are at least partially metalized, in particular plastic products made of moulded polyolefin, are often used for making packaging for cosmetic products, such as packaging for powder compact, mascara, lipstick or for perfumes such as vaporisers, etc., or part thereof such as lid, collar, bottle, flask, dressing.

Metallisation is a general term designating any method intended to cover the surface of a non-metallic object of a metal layer. Physical vapour deposition (also commonly called “PVD” or even vacuum metallisation) is a typical example of such a method.

PVD is performed under vacuum. The metal to be deposited on the surface of the object is typically used in the form of wire or lamella placed on tungsten filaments which are heated to sublimation. The resulting metal vapour is deposited on all the surfaces present inside the vacuum chamber. This particular modality of PVD is generally called thermal evaporation.

A conventional vacuum metallisation process of a plastic product, more particularly made of rigid polyolefin comprises four main steps:

a) activation of adherence, typically by flaming, treatment corona, plasma, cathodic effluvation, or deposit of a primary bonding layer (organic), or a combination thereof;

b) application of an organic basecoat, typically of dry thickness of around 10 to 20 μm;

c) vacuum metallisation, typically using aluminium, until the thickness of the metal layer reaches around 40 to 80 nm; and

d) application of a protective and translucid organic topcoat which is coloured or not, and whereof the thickness is typically around 5 to 10 μm. The metalized plastic product obtained by this process therefore successively comprises a basecoat disposed directly on the plastic body of the product previously treated to activate adherence, a layer of metal and a topcoat (otherwise called ‘protective layer’ or ‘finishing layer’ in French). Before the sublayer there could also be a primary bonding layer.

Flaming essentially consists of oxidation and cleaning of the surface of the product to boost its surface tension (from around 30-32 dynes/cm to at least 36-44 dynes/cm) to ensure adherence of subsequent coating and decrease the presence of products of low molecular weight which could impair adherence. The flame is produced by mixing gas (methane, propane, butane) with air in more or less stoechiometric proportions for optimisation of combustion. The flame is applied by a burner provided specifically for this.

Treatment by corona and by plasma consists of using high voltage to generate an electric arc (current) at atmospheric pressure from an electrode. The electric arc increases the surface tension of the surface of the product. In general, the electrode must be at most spaced around 10 mm from the substrate in each case.

The plasma and the cathodic effluvation can be applied under vacuum, enabling more substantial and complex treatment of surfaces. These processes under vacuum are often carried out in the presence of different gases (argon, oxygen, nitrogen, etc.) so that the chemical composition of the surface of the product can be varied to better adapt it to the chemical nature of the subsequent coating. The plasma is generated by a DC, radiofrequency or microwave generator.

The primary bonding layer, applied directly on the surface of the plastic body, improves adherence of the metal layer. This primary bonding layer is typically applied by pulverisation (pistol). The formulation for the primary bonding layer typically comprises resin de type polyolefin chlorinated at very low concentration in a solvent, and which dries in air without polymerisation. The thickness of the layer once dried is minimal, at most a few micrometers and often less than a micrometer.

The basecoat is a layer of organic resin applied prior to metallisation. The basecoat most often comprises polymerised resins. These resin substances are mainly of the polymerisable acrylate type, typically polymerisable by ultraviolet. They are diluted in solvent to lower the viscosity sufficiently so they can be applied by pulverisation (pistol). Dilution also ensures proper wetting of the substrate. The basecoat is applied to ensure proper surface smoothing and also allow good adherence of the metal. The thickness of a basecoat is adapted according to the quality of the surface of the substrate.

A major disadvantage of this conventional method relates to the number of steps required to produce the finished product. Consequently, the finished product is a complex product requiring complicated and costly operations. This is why it would be advantageous to provide a process comprising a reduced number of steps, less costly for making at least partially metalized plastic products.

A manufacturing process which dispenses with the application step of a basecoat is known from document WO 2009/112188 for simplifying the manufacturing process. Inter alia this is due to a particular selection of moulding conditions, the design of the mould used, the quality of materials employed. This process produces a plastic product whereof the body has a sufficiently smooth surface for direct metallisation of the latter.

However, in a plastic product made of polyolefin, more particularly polypropylene or polypropylene copolymer, obtained by this process—contrary to other non-polyolefin substances such as acrylonitrile butadiene styrene (ABS), styrene acrylonitrile (SAN), polyamide, etc.—the application of a topcoat on the metal layer seems to cause adherence defects between the metal and the plastic, and this includes with metallisation by sputtering which results in better adherence between the plastic and the metal than thermal evaporation due to deposition energy which is several times higher. In fact, it seems that adherence is reduced significantly after application of the topcoat in this specific case.

To rectify this adherence defect on the plastic polyolefin, it would normally be necessary to conduct an extra step of application of an organic basecoat, or even also an additional adherence activation step, for example by flaming, corona treatment or preferably by plasma treatment (either done at atmospheric pressure or under vacuum), and a few times the application of a primary bonding layer or a combination of these processes to the plastic body prior to metallisation, such as already described hereinabove.

The primary bonding layer clearly improves adherence of the organic basecoat, the polyolefin being inert by nature.

However, this goes against what the inventors are trying to achieve. In fact, at least one step is added to the manufacturing process.

Also, the extra step for adherence activation, which is preferably performed by plasma treatment, involves added costs due to the additional equipment necessary. In addition, plasma treatment (or other processes giving an equivalent result) can heat or modify the surface of the plastic body and make it more rugged. It is known that the less smooth the initial surface of the plastic body prior to metallisation, the more mediocre still (multiplier effect) the aspect of the latter is after metallisation and application of the topcoat (see for example “Influence of the structure of composite films on the reflectance of plastics metalized under vacuum”, or again “Influence of composite film structure on reflectance of vacuum metalized plastics” in the original version, by Hoffman and Dickie, in Polymer Engineering and Science, December 1977, vol. 17. No. 12).

There is therefore a need to find a solution which enables no only the diminution of the number of operations necessary for manufacture, but which at the same time ensures good adherence of the metal to the plastic body of the polyolefin product, including after application of a topcoat.

During extensive research, the inventors were able to unexpectedly identify families of polyolefins which allow good adherence of the metal layer to the plastic body without the need for any application steps of an organic basecoat and adherence activation. These identified polymers also retain good adherence when an overprotective layer is applied to the metal layer.

### PRESENTATION OF THE INVENTION

An aim of the invention is therefore to eliminate at least one disadvantage of the prior art presented hereinabove. In particular, an aim of the invention is to obtain an at least partially metalized plastic product in which the metal layer adheres sufficiently to the surface of the plastic body, decreasing the number of operations necessary for surface metallisation of the plastic body.

This aim is attained by the at least partially metalized plastic product comprising a plastic body, the plastic body being directly covered at least partially by a metal layer. The product can be entirely metalized.

In the sense of the present description the term “directly” means that the plastic body is covered by a metal layer without the presence of an intermediate layer interposed between the plastic body and the metal layer. This term excludes the application of an organic basecoat and carrying out adherence activation by flaming, corona, plasma, or cathodic effluvation, or by application of a primary bonding layer (organic), or a combination of the latter.

In this plastic product the plastic is a polyolefin selected from polyethylene, polypropylene, their copolymers or their mixtures.

When the polyolefin comprises at least one polypropylene or a copolymer of polypropylene-polyethylene, this polyolefin has an infrared spectrum having:
either a peak at the wave number of 720 cm⁻¹ of a height at least equal to 20;
or if there is no peak at the wave number of 720 cm⁻¹, a peak at the wave number of 809 cm⁻¹ of a height less than 20, preferably 16, a peak at the wave number of 840 cm⁻¹ of a height less than 50, preferably less than 45, more preferably at 10, a peak at the wave number of 899 cm⁻¹ of a height less than 20, preferably 6, and a peak at the wave number of 997 cm⁻¹ of a height less than 60, preferably 18.

“Metalized” means that the plastic body comprises a metal layer on at least part of its visible surface. This layer preferably has a thickness of between 10 and 100 nm, advantageously between 20 and 80 nm. If the metal layer must have an opaque appearance, the thickness is preferably at least from 30 to 40 nm in the case of aluminium. The metal used for the metal layer can be pure metal or an alloy. Examples of metals are aluminium, silver, nickel, chrome, copper, titanium and gold. Examples of alloys are stainless steel and aluminium/copper alloys. That said, today in over 90% of cases the preferred metal is aluminium because of its superior reflectance and its low cost.

A surface visible is defined as a surface which can be viewed during normal use of the plastic product.

“Polyethylene” is a homopolymer obtained by synthesis from ethylene.

“Polypropylene” is a homopolymer obtained by synthesis from propylene.

“Polypropylene copolymer-polyethylene” originates from copolymerisation of propylene with ethylene.

The wavelengths of the peaks and their amplitude (as a percentage relative to a standard peak) are measured by a process described in detail hereinbelow.

The advantage of such a polyolefin is that the adherence obtained between the metal layer and the surface of the plastic body is sufficient after application of topcoat. This plastic product satisfies tests conducted on the products after manufacture.

A topcoat can be applied directly in contact with the metal coating to protect it. For cosmetics and perfumes packaging, the topcoat must not only resist repetitive handling and normal wear relative to use by the end consumer, but must also resist cosmetic products with which it can be put in contact, perfumes in particular. This requirement requires particularly resistant special formulations for the topcoat, usually comprising acrylates sensitive to ultraviolet radiation. This type of topcoat which is necessarily hard and resistant can engender stress on the lower layers, causing adherence problems, including adherence between the metal and the plastic. But the use of polyolefins identified hereinabove avoids adherence problems, especially that between the metal and the plastic.

In a preferred variant, the plastic product comprises such a topcoat.

In a first variant, the polyolefin is polyethylene, preferably high-density polyethylene. “High-density polyethylene” is typically polyethylene of a density between 0.940 g/cm³ and 0.977 g/cm³. In a second variant, the polyolefin is a copolymer of polypropylene-polyethylene. In a third variant, the polyolefin is a mixture of polyethylene with polypropylene. In a fourth variant, the polyolefin is a mixture of polyethylene with a copolymer of polypropylene-polyethylene. In a fifth variant, the polyolefin is a mixture of polypropylene with a copolymer of polypropylene-polyethylene.

The invention also relates to a process for the manufacture of a product such as presented hereinabove comprising the metallisation step under vacuum directly on the blank surface of the plastic body of the product. This process is illustrated in FIG. 2.

An advantage of this process is to economise both on the application step of organic basecoat and the adherence activation step. In fact, the application step of an organic basecoat prior to the metallisation step such as necessary in conventional processes is made superfluous here by the particular choice of plastic; with the polyolefins mentioned, the metal layer adhere sufficiently even without organic basecoat and also in the of topcoat. Also, the adherence activation step has been omitted.

The metallisation step can be performed by cathodic pulverisation.

Cathodic pulverisation consists of bombarding a sample of the metal or the metal alloy to be deposited by argon ions in magnetically reinforced plasma. The bombardment of argon ions causes ejection of molecules of the metal or the metal alloy to be deposited to the surface of the plastic body. The ejection of molecules occurs at energy greater than that of thermal evaporation. Consequently, adherence of the metal to the surface of the plastic body is improved.

More particularly, cathodic pulverisation to which reference is made here is typically non-reactive, that is, cathodic pulverisation is conducted under partial vacuum in the presence of inert gas, generally argon. Non-reactive cathodic pulverisation, which allows deposit of pure metal, is a faster method easier to control than reactive cathodic pulverisation which leads to depositing metal oxides and nitrides. During production, cathodic pulverisation is performed in a reaction chamber size range from a small chamber of capacity less than 50 litres with cycle times of a few seconds to a large single chamber, for example 2 meters in diameter with cycle times from 10 to 30 minutes as a function of the pumping system utilised.

Usually, the vacuum is created inside a reaction chamber in which the plastic body is disposed due to a pumping system of up to around 10⁻⁴ at 10⁻⁵ mbar. A controlled quantity of inert gas, generally argon, is injected inside the chamber by simple pressure differential until the latter reaches around 10⁻³ mbar. The metal to be deposited is used in the form of a circular or rectangular plate and is called “target”. The thickness of the target is typically less than 20 mm and the latter is mounted on a magnetron of the same form and cooled by water. The magnetron typically consists of a network of three neodymium magnets in which the magnets are disposed so that the polarities are alternating: N—S—N or S—N—S, to generate a dual magnetic field in which the target is bathed. High voltage, typically provided by a continuous or pulsed voltage source, is applied so that the target is charged negatively to form a cathode. Plasma is then generated and leads to the target by action of the magnetic field. The excited electrons of the plasma collide with the argon atoms in the reaction chamber to produce positively charged argon ions being directed to the target via electrostatic attraction. Collisions of argon ions with the target cause high-energy atom ejection of the target inside the chamber and in particular towards the surface of the plastic body to be metalized. Cathodic pulverisation takes place at higher pressure than thermal evaporation, consequently the mean free path of the ejected atoms is shorter. This is why the distance from the plastic body to the target is typically 250 to 500 mm for thermal evaporation; the latter is generally 5 to 10 times less for cathodic pulverisation. The high energy necessary for this method involves stronger heating of the plastic body. But for layers of metal of a thickness less than 100 nm this is not generally a problem. The deposit speed of a given metal depends on the distance of the target and of the power used, which typically varies between 5 and 50 W/cm² and the duration of deposit can vary no less than a second to more than a minute.

Cathodic pulverisation allows the use of metals other than aluminium, such as silver, nickel, stainless steel, chrome, copper, aluminium/copper alloys, gold, titanium. In particular, these different metals can be selected as a function of their colour, to the point where no colouring agent is used in the topcoat.

Also, it has been determined empirically that cathodic pulverisation provided sufficient energy relative to thermal evaporation to reach a sufficient degree of adherence of the metal directly on the surface of the plastic product, even without an adherence activation step. This can be explained by the fact that cathodic pulverisation is conducted with a conventional DC magnetron which involves energy levels 5 to 10 times greater than energy levels used for thermal evaporation, resulting in improved adherence.

The product described hereinabove is advantageously used for the manufacture of at least one part of packaging for a cosmetic or perfume product.

The process can finally comprise an application step of an overprotective layer on the metal layer. The overprotective layer is applied to give the metalized plastic product better resistance to any physical or chemical damage of the metal layer which is extremely fine and fragile since its thickness is of the order of 10 to 100 nm only, and of at least 40 to 80 nm if an opaque appearance is wanted. The thickness of the metal layer is intentionally selected in this order so that the time necessary for PVD is the shortest possible.

In a preferred variant, the process comprises an application step of this overprotective layer.

The whole process can be undertaken “in-line” on the same production chain; i.e. the different steps are conducted within a closed and restricted space. In particular, the moulding step of the plastic body and the metallisation step are conducted automatically and continuously by means of automation means. There is no intervention on the part of a human operator between the input of a moulding unit and the output of a metallisation unit of the production chain, reducing handling and transport of the plastic product. Now, handling and transport are sources of significant contamination of the product. Also, the time needed for completing moulding and metallisation of the plastic body can be reduced to under 5 minutes.

### PRESENTATION OF THE DIAGRAMS

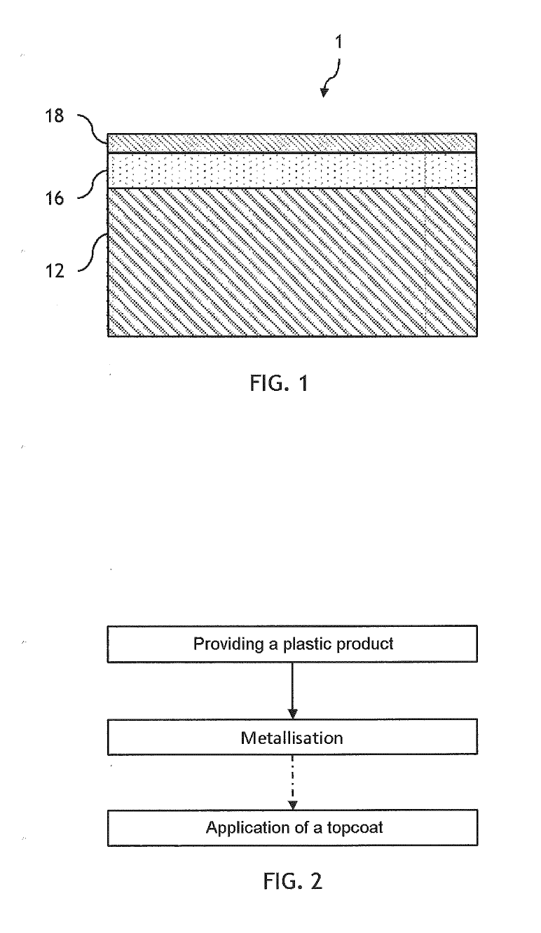

FIG. 1 schematically illustrates a metalized plastic product according to the invention. The plastic product 1 of FIG. 1 comprises a plastic body 12 covered directly by a metal layer 16. To protect the metal layer 16, a topcoat 18 has been applied to the metal layer 16. No organic basecoat or primary bonding layer has been utilised.

FIG. 2 is an organization chart presenting the different steps of a procedural metallisation example according to the invention.

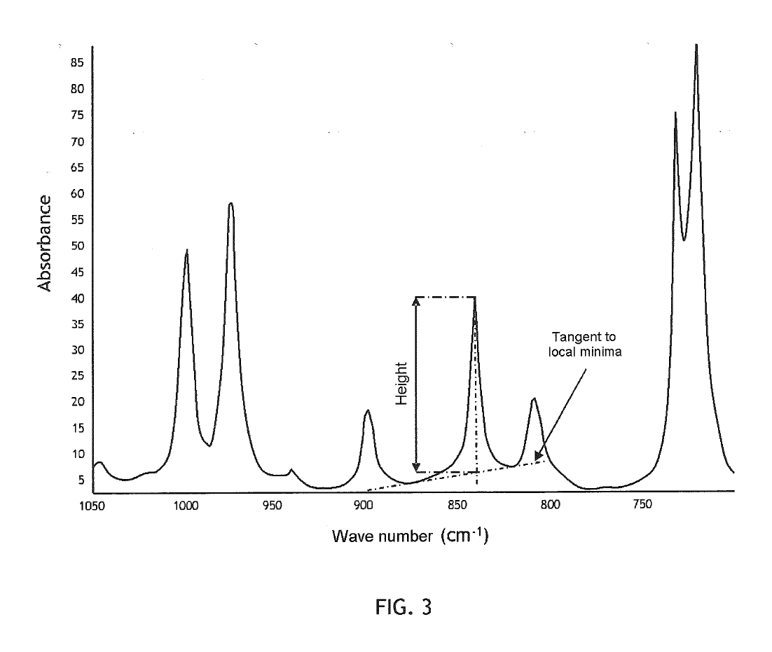

FIG. 3 is an example of an IR spectrum obtained and shows the method for determining the height of the peaks.

### METHOD

Measuring by Infrared Spectrometry

Equipment: a 00-285 Beckmann heating press, a Nicolet 710 P infrared spectrometer, and a support plate.

Operating method: a film of the plastic to be examined is made by hot-pressing in the 00-285 Beckmann heating press.

An infrared spectrum in transmission is then obtained with the Nicolet 710 P infrared spectrometer. For this, the film is placed on the support plate of the infrared spectrometer and held in place by a magnet. The support plate is then positioned in the cell of the spectrometer provided for this purpose such that the laser beam passes through the film in its centre. A raw infrared spectrum of the film is acquired, followed by acquisition of the baseline (without film). The baseline is then subtracted from the raw infrared spectrum of the film to get the infrared spectrum in transmission of the latter.

The infrared spectrum in transmission is then converted to infrared spectrum in absorbance (automatic function of the spectrometer). In practice, the absorbance value at a wave number is given by measuring the height of the absorption peak corresponding to this wave number. Measuring the height of the peak at a given wave number is performed by tracing the baseline of the peak and by measuring the height between this baseline and the apex of the peak, as illustrated in FIG. 3. The base formula of the absorbance at a given wavelength is:

Aₗ=log₁₀(l₀/l),

with l₀ corresponding to the intensity of light before the beam passes through the sample and 1 corresponding to the intensity of the light transmitted.

The absorbance therefore varies between 0 (l=l₀) and infinity (l=0) and depends on the wavelength, the concentration of the substance in the examined medium and the examined medium.

The Beer-Lambert law, which connects the absorbance value to the concentration of a substance in the traversed medium, gives the following formula:

Aₗ=e·l·c,

with ‘c’ the concentration of a substance in the traversed medium expressed in ‘e’ the coefficient of molar extinction of the substance expressed in L·mol⁻¹·cm⁻¹ and ‘l’ the length of the optical path traversed by the light in the medium expressed in cm. In the case examined, the length of the optical path is equal to the thickness of the sample.

Accordingly, at a given wavelength, for a given medium and for a given substance:
for a sample thickness l₁, there is:

A₁=e·l₁·c hence A₁/l₁=e·c (1)
for a sample thickness l₂, there is:

A₂=e·l₂·c hence A₂/l₂=e·c (2)

Hence A₁/l₁=A₂/l₂=e·c, and then:

A₂=A₁·l₂/l₁ (3)

As specified hereinabove, the absorbance values obtained at the different wave numbers depend on the thickness of the sample analysed. For a comparison to be made between different samples it is therefore important to recalculate the absorbances by taking a length of optical path common to all the samples. This length, which corresponds in the case examined to the thickness of the sample, is generally fixed at 1 cm (l₂=1 in equation 3). This operation, which consists of dividing the absorbance value at each wavelength by the thickness of the sample expressed in cm, is called ‘normalisation’.

Adherence Test on Adhesive Strip (a)

The test used is that from the standard ASTM D3359/39.

Equipment: a six-tooth grid comb, teeth spaced at 1 mm (preferably a comb from the company ERICHSEN, reference 295/1); adhesive tape having adhesive strength of between 350 and 450 cN/cm² and a width of around 19 mm (adhesive tape by the company 3M, reference 616).

Operating method: with the help of the comb, two networks of perpendicular furrows are made on the metalized surface of the plastic product. The two networks form a grid.

The metalized and gridded surface is cleaned by means of a fine brush.

The adhesive tape is applied to the metalized and gridded surface by finger pressure to ensure proper contact of the adhesive tape on the surface.

A rest time of one minute is observed, then the adhesive tape is rapidly removed shock-free at an approximate angle of 180°.

This test is repeated on expiry of a week then a month.

Interpretation of results: the tested samples are examined. A rating of 0 to 5 is attributed according to the appearance of the metalized surface after the adherence test. A rating of 0 signifies that over 65% of the metal layer at the level of the grid has been removed. A rating of 5 signifies that the metal layer at the level of the grid has not been removed (with the exception of furrows from passing of the comb).

The metalized plastic used for the sample is considered as having passed the test successfully when the rating is 5.

Humidity Resistance Test (b)

The test is conducted in a closed chamber, with the metalized plastic product to be tested placed above the water heated to 55° C. The exposure time is 48 hours, after which the metalized plastic product is withdrawn then wiped with a clean and non-abrasive cloth. There must not be any traces of attack, icing, or any other visual modification of the metalized plastic product.

This test is repeated on expiry of a week then a month.

Perfume Resistance Test (c)

The metalized surfaces of the plastic products are moistened with commercially available perfume, for example Addict™ by Christian Dior, or a standard product, for example G1 by I'Oreal, then the products made of metalized plastics are enclosed individually in a plastic sachet and left at ambient temperature, typically 20° C., for 48 hours after which the metalized plastic products are taken out and wiped with clean and non-abrasive cloth. There must not be any traces of attack, icing, or any other visual modification of the metalized plastic product.

This test is repeated on expiry of a week then a month.

Preparation of Samples for the Examples

The plastic samples are obtained by injection of various polyolefins separately in a multi-cavity mould according to injection moulding methods known to the person skilled in the art and according to the optimal criteria described in document WO 2009/112 188.

The samples are placed in a container at ambient temperature, that is, around 20° C. A layer of aluminium is then deposited directly onto the outer surface of the pieces by cathodic pulverisation in a chamber of approximately 2 litres, in conditions identical for all the samples, in the presence of argon so as to install pressure of around 7×10⁻³ mbar. The target is an aluminium cathode. The deposit time is controlled as a function of the energy produced and lasts around 2.0 seconds, so as to contribute constant energy to all the samples tested. Each sample is placed at a constant distance of around 30 mm from the surface of the target. The power of cathodic pulverisation is adjusted to around 20 W/cm².

It should be specified that no organic basecoat and no primary bonding layer has been applied to the surface of the samples prior to deposit of the metal layer. Also, no treatment has been conducted prior to deposit of the metal layer.

### EXAMPLES

The examples hereinbelow are plastics which have undergone the three tests (a), (b) and (c); that is, they have adequate properties in terms of adherence, resistance to humidity and exposure to perfume.

### Example 1

### PP and PE Copolymers

| | Wave number (cm⁻¹) | | | | |
|---|---|---|---|---|---|
| Plastic | 997 | 899 | 840 | 809 | 720 |
| 1. Basell Clyrell ® EC340 | 55.9 | 17.1 | 45.5 | 18.2 | 55.2 |
| 2. Exxon Vistamaxx 6202 | 16.9 | 5.7 | 6.0 | 15.8 | 0.0 |

These polyolefins are polypropylene copolymers made in the presence of a catalyst of metallocene type.

### Example 2

### Mass Mixtures at 50/50 PP and PP Copolymer

| | Wave number (cm⁻¹) | | | | |
|---|---|---|---|---|---|
| Plastic | 997 | 899 | 840 | 809 | 720 |
| 3. Total PPH7060 + Exxon | 59.4 | 16.0 | 43.8 | 18.5 | 0.0 |
| Vistamaxx ® 6202 | | | | | |
| 4. Total PPH7060 + Basell | 59.0 | 24.0 | 55.0 | 25.0 | 33.0 |
| Clyrell ® EC340 | | | | | |
| 5. Total PPR9220 + Exxon | 54.0 | 16.0 | 39.0 | 19.0 | 0.0 |
| Vistamaxx ® 6202 | | | | | |
| 6. Total PPR9220 + Basell | 56.0 | 22.0 | 47.0 | 22.0 | 33.0 |
| Clyrell ® EC340 | | | | | |

The TOTAL PPH7060 is polypropylene manufactured in the presence of catalyst of Ziegler-Natta type.
The TOTAL PPR9220 is a copolymer of polypropylene manufactured in the presence of catalyst of Ziegler-Natta type.

### Example 3

### Mass Mixtures at 50/50 PP and HDPE

| | Wave number (cm⁻¹) | | | | |
|---|---|---|---|---|---|
| Plastic | 997 | 899 | 840 | 809 | 720 |
| 7. Total PPH7060 + HDPE1 | 46.0 | 17.0 | 36.0 | 17.0 | 63.0 |
| 8. Total PPH7060 + HDPE2 | 48.8 | 15.8 | 38.2 | 16.4 | 70.7 |
| 9. Total PPR9220 + HDPE1 | 37.0 | 13.0 | 33.0 | 13.0 | 91.0 |
| 10. Total PPR9220 + HDPE2 | 43.3 | 14.3 | 33.7 | 14.1 | 85.7 |

HDPE1 is DOW KT 1000UE;
HDPE2 is SABIC PEHD M100053.

### Example 4

### Mass Mixtures at 75/25 PP and HDPE

| | Wave number (cm⁻¹) | | | | |
|---|---|---|---|---|---|
| Plastic | 997 | 899 | 840 | 809 | 720 |
| 11. Total PPH7060 + HDPE1 | 23.0 | 7.8 | 21.0 | 8.1 | 58.0 |
| 12. Total PPH7060 + HDPE2 | 26.0 | 8.8 | 24.0 | 9.0 | 82.0 |
| 13. Total PPR9220 + HDPE1 | 19.0 | 6.2 | 17.0 | 6.3 | 73.0 |
| 14. Total PPR9220 + HDPE2 | 22.0 | 6.5 | 20.0 | 6.5 | 92.0 |

### Example 5

### 100% HDPE

| | Wave number (cm⁻¹) | | | | |
|---|---|---|---|---|---|
| Plastic | 997 | 899 | 840 | 809 | 720 |
| 15. HDPE1 | 0.0 | 0.0 | 0.0 | 0.2 | 171.0 |
| 16. HDPE2 | 0.0 | 0.0 | 0.0 | 0.0 | 121.0 |
| 17. Total M6091 | 0.0 | 0.0 | 0.0 | 0.1 | 67.0 |

### COMPARATIVE EXAMPLES

The comparative examples hereinbelow are plastics which have not undergone at least one of the three tests (a), (b) and (c); that is, they are not adequate in terms of adherence and/or resistance to humidity and/or exposure to perfume.

### Comparative Example 1

### PP (Homopolymer)

| | Wave number (cm⁻¹) | | | | |
|---|---|---|---|---|---|
| Plastic | 997 | 899 | 840 | 809 | 720 |
| 18. Total PPH7060 | 92.5 | 31.2 | 70.6 | 32.2 | 0.0 |

Comparative Example 2

### PP and PE Copolymers

| | Wave number (cm⁻¹) | | | | |
|---|---|---|---|---|---|
| Plastic | 997 | 899 | 840 | 809 | 720 |
| 19. Total MR30MC2 | 65.5 | 22.4 | 51.7 | 22.2 | 0.0 |
| 20. Total PPR9220 | 67.2 | 24.8 | 55.5 | 24.9 | 0.0 |

Comparative Example 3

### Mass Mixtures at 80/20 PP and PP Copolymer

| | Wave number (cm⁻¹) | | | | |
|---|---|---|---|---|---|
| Plastic | 997 | 899 | 840 | 809 | 720 |
| 21. TotaL PPH7060 + Exxon | 71.6 | 24.5 | 68.0 | 27.1 | 0.0 |
| Vistamaxx ® 6202 | | | | | |

In the comparative examples hereinabove, it is remarkable that plastics not having a peak at the wave number of 720 cm⁻¹ and having at least one peak at the wave number 997, 899, 840 or 809 cm⁻¹ exceed the thresholds defined earlier, i.e. respectively 20.0; 50.0; 20.0 and 60.0 are inadequate for direct metallisation. In fact, these plastics exhibit adherence, resistance to humidity and perfume exposure which is too mediocre for them to be used for making at least partially metalized plastic products according to the process of the invention.

1. An at least partially metalized plastic product, comprising a plastic body, the plastic body being directly covered at least partially by a metal layer,
characterised in that the plastic is a polyolefin selected from polyethylene, polypropylene, their copolymers or their mixtures;
and in that when the polyolefin comprises at least one polypropylene or a copolymer of polypropylene-polyethylene, the polyolefin has an infrared spectrum having:
a peak at the wave number of 720 cm⁻¹ of a height at least equal to 20; or
if there is no peak at the wave number of 720 cm⁻¹, a peak at the wave number of 809 cm⁻¹ of a height less than 20, a peak at the wave number of 840 cm⁻¹ of a height less than 50, a peak at the wave number of 899 cm⁻¹ of a height less than 20, and a peak at the wave number of 997 cm⁻¹ of a height less than 60.

2. The product according to claim 1, further comprising a topcoat directly in contact with the metal layer.

3. The product according to claim 1 wherein the polyolefin is polyethylene.

4. The product according to claim 1 wherein the polyolefin is a copolymer of polypropylene-polyethylene.

5. The product according to claim 1 wherein the polyolefin is a mixture of polyethylene with polypropylene.

6. The product according to claim 1 wherein the polyolefin is a mixture of polyethylene with a copolymer of polypropylene-polyethylene.

7. The product according to claim 1 wherein the polyolefin is a mixture of polypropylene with a copolymer of polypropylene-polyethylene.

8. The product according to claim 1 wherein the metal is selected from the group consisting of aluminium, silver, nickel, chrome, copper, titanium, gold, and their alloys.

9. A manufacturing process of a product claim 1, comprising a metallisation step under vacuum directly on the untreated surface of the plastic body to produce the metal layer.

10. The process according to claim 9, further comprising an application step of a protective layer on the metal layer.

11. The process according to claim 9, wherein the metallisation step is performed by sputtering.

12. (canceled)

13. The product according to claim 1 wherein the plastic product is fully metalized.

14. The product according to claim 1 wherein the polyolefin has an infrared spectrum having a peak at the wave number of 809 cm⁻¹ of a height of 16, a peak at the wave number of 840 cm⁻¹ of a height of 10, a peak at the wave number of 899 cm⁻¹ of a height of 6, and a peak at the wave number of 997 cm⁻¹ of a height of 18.

15. The product according to claim 1 wherein the metal is steel.

16. The product according to claim 1 wherein the plastic product wherein the polyolefin is high density polyethylene.
